(19) United States
(12) Patent Application Publication
(10) Pub. No.: US 2012/0129290 A1
(43) Pub. Date: May 24, 2012

(54) METHOD FOR FORMING SEMICONDUCTOR NANO-MICRO RODS AND APPLICATIONS THEREOF

(75) Inventor: CHING-FUH LIN, Taipei (TW)

(73) Assignee: NATIONAL TAIWAN UNIVERSITY, Taipei (TW)

(21) Appl. No.: 13/041,142

(22) Filed: Mar. 4, 2011

(30) Foreign Application Priority Data
Nov. 24, 2010 (TW) 099140471

(51) Int. Cl. H01L 21/20; H01L 31/18; H01L 33/04; B82Y 99/00

(52) U.S. Cl. 438/47; 438/478; 438/94; 977/762; 257/E31.02; 257/E33.008

(57) ABSTRACT

An embodiment of this invention utilizes ZnO rods as the etching mask to etch a GaN layer arranged below, so that GaN rods are formed. The GaN rods have similar patterns as the ZnO rods. The pattern, size, position, and height of the GaN rods are respectively controlled by the pattern, size, position, and height of the ZnO rods.

### CROSS REFERENCE TO RELATED APPLICATIONS

The entire contents of Taiwan Patent Application No. 099140471, filed on Nov. 24, 2010, from which this application claims priority, are incorporated herein by reference.

### BACKGROUND OF THE INVENTION

1. Field of the Invention

The present invention relates to methods for forming semiconductor nano-micro rods and their applications.

2. Description of Related Art

During the fabrication of optoelectronics or electronics, the quality of the components is usually decreased due to the dislocations of the epitaxial layer. For example, prior arts typically employ the epitaxy process to grow a semiconductor nano-micro rods array on a substrate; because the semiconductor nano-micro rods array and the substrate have different lattice constant, result in dislocations in the array, and the thicker are the semiconductor nano-micro rods, the denser are the dislocations. (In this text, the term “nano-micro” refers to “nanometer scale” or “micrometer scale.”)

In addition, when the epitaxy process is employed to grow a semiconductor nano-micro rods array, e.g., a gallium nitride (GaN) nano-micro rods array, it cannot precisely control the pattern, position, size, and the height of the GaN rods.

Accordingly, it would be advantageous to develop a novel method for fabricating semiconductor nano-micro rods and precisely controlling their pattern, position, size, and the height, and thus fabricating epitaxial layer with low density of dislocations, which can be used to produce various optoelectronics or electronics.

### SUMMARY OF THE INVENTION

An object of the present invention is to provide a novel method for fabricating semiconductor nano-micro rods and precisely controlling their pattern, position, size, and the height, and thus fabricating epitaxial layer with low density of dislocations, which can be used to produce various optoelectronics or electronics.

Accordingly, an embodiment of this invention provides a method for forming semiconductor nano-micro rods, comprising the steps of: providing a substrate; forming a first semiconductor epitaxial layer on the substrate; forming a photoresist layer or a barrier layer on the first semiconductor epitaxial layer and defining a plurality of apertures in the photoresist layer or the barrier layer; respectively growing a semiconductor nano-micro rod mask on each of the apertures; and etching the first semiconductor epitaxial layer by the semiconductor nano-micro rod masks to form a plurality of semiconductor nano-micro rods,

### BRIEF DESCRIPTION OF THE DRAWINGS

FIG. 1A to FIG. 1F (or 1F′) show a method for forming semiconductor nano-micro rods according to a preferred embodiment of the present invention.

FIG. 2A to FIG. 2C show one or more epitaxy processes are performed on the as-prepared structure shown in FIG. 1F′; the same processes may be applied to the structure shown in FIG. 1F.

FIG. 3A to FIG. 3C show one or more epitaxy processes are performed on the as-prepared structure shown in FIG. 1F; the same processes may be applied to the structure shown in FIG. 1F′.

FIG. 4A to FIG. 4D show one or more epitaxy processes are performed on the as-prepared structure shown in FIG. 1F; the same processes may be applied to the structure shown in FIG. 1F′.

### DESCRIPTION OF THE PREFERRED EMBODIMENT

Reference will now be made in detail to specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known components and process operations are not described in detail in order not to unnecessarily obscure the present invention. While drawings are illustrated in detail, it is appreciated that the quantity of the disclosed components may be greater or less than that disclosed, except where expressly restricting the amount of the components.

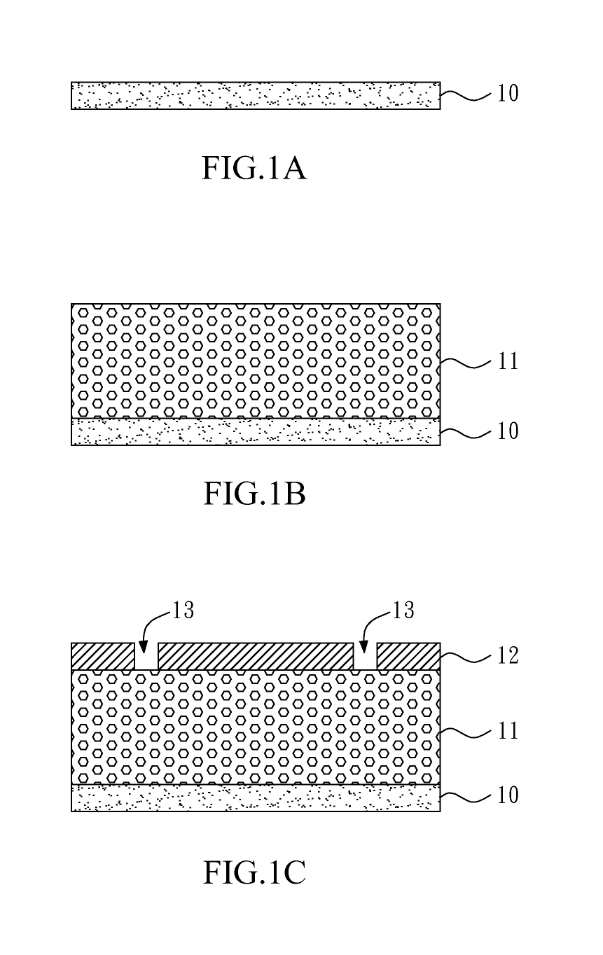

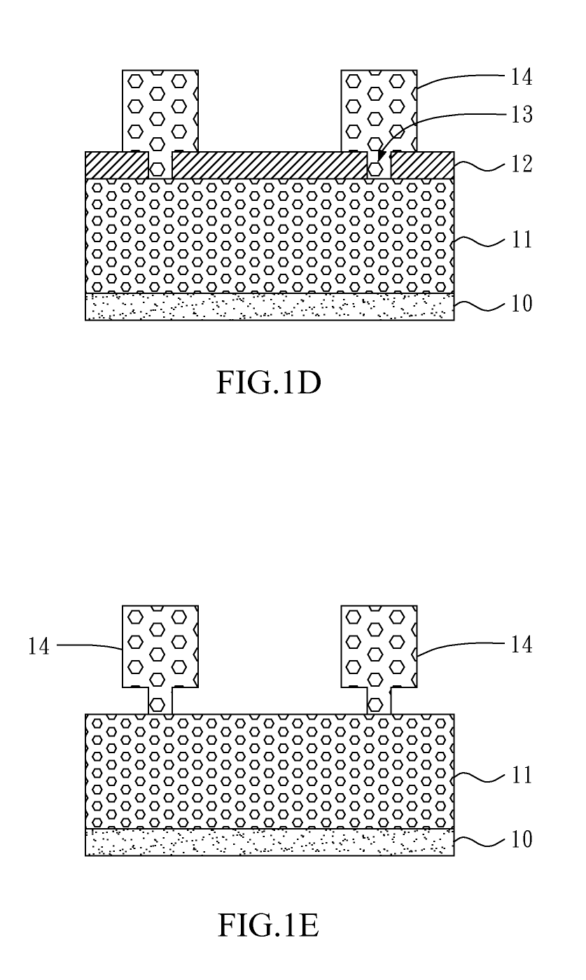

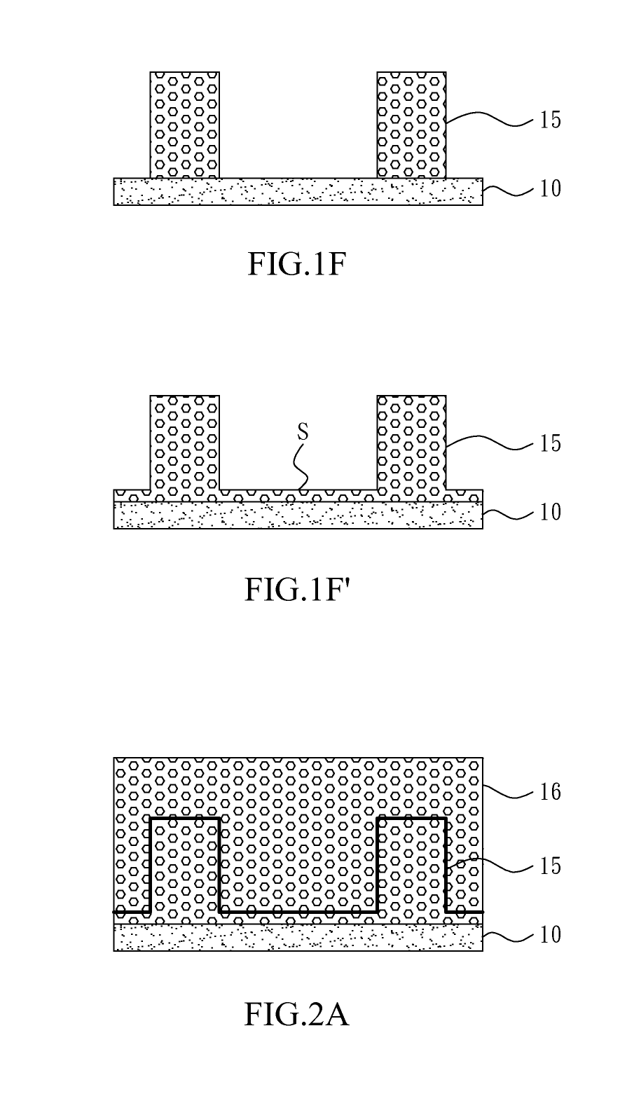

FIG. 1A to FIG. 1F (or 1F′) show a method for forming semiconductor nano-micro rods according to a preferred embodiment of the present invention. In this text, the term “nano-micro rods” refers to “nanometer or micrometer scale rods with nanometer or micrometer scale spacing.”

Referring to FIG. 1A, a substrate 10, such as a sapphire substrate, is provided. Referring to FIG. 1B, then, an epitaxy process is performed to form a first gallium nitride (GaN) layer 11, whose crystal lattice is preferably single crystal or similar to single crystal, on the substrate 10. The epitaxy process may comprise Metal-Organic Chemical Vapor Deposition (MOCVD), Molecular Beam Epitaxy (MBE), Migration-enhanced Metal-Organic Chemical Vapor Deposition (MEMOCVD), or other suitable methods known in the art.

Referring to FIG. 1C, then, a patterned photoresist layer 12 is formed on the first GaN layer 11 and apertures 13 are thus defined in the photoresist layer 12. This step can be performed by methods known in the art, such as photolithography or E-beam lithography. For example, a photoresist layer is first coated on the first GaN layer 11, and then a pattern is transferred to the photoresist layer by light, and thus apertures 13 are defined. In another embodiment, instead of the patterned photoresist layer 12, an anode aluminum oxide layer with apertures 13 to exposure GaN underneath, used as a barrier layer 12, is arranged on the first GaN layer 11.

Referring to FIG. 1D, then, a plurality of zinc oxide (ZnO) nano-micro rods 14 are formed on the apertures 13. This embodiment employs hydrothermal synthesis to form the ZnO nano-micro rods 14. First, a ZnO seed layer is coated on the apertures 13. After that, an aqueous solution containing the reactants, such as zinc nitrate hexahydrate [Zn(NO₃)₂.6H₂O] and methenamine (C₆H₁₂N₄), is placed in an autoclave with controlled high pressure and suitable temperature (may be below 100° C.), to grow ZnO nano-micro rods 14 on the ZnO seed layer.

Referring to FIG. 1E, the photoresist layer 12 or the barrier layer 12 is removed by acetone or plasma, for example.

Referring to FIG. 1F, by using the ZnO nano-micro rods 14 as the mask, the first GaN layer 11 is etched to form GaN nano-micro rods 15. After the GaN nano-micro rods 15 are formed, an etching solution such as hydrochloric acid may be used to remove possible remaining ZnO nano-micro rods 14.

Alternatively in another embodiment, referring to FIG. 1F′, by using the ZnO nano-micro rods 14 as the mask, the first GaN layer 11 is etched to form GaN nano-micro rods 15, and the etching depth is controlled to remain a GaN surface S such that the substrate 10 will not be exposed.

The above embodiment employs hydrothermal synthesis to grow ZnO nano-micro rods 14 on the first GaN layer 11 and within the apertures 13. The solution process can significantly reduce the fabricating cost. By adjusting the concentration of the reactants and the surface area of the ZnO seed layer, the size of the ZnO nano-micro rods 14 can be controlled. If the size of the apertures 13 is large, then the size of the ZnO nano-micro rods 14 will have similar size as the apertures 13. If the size of the apertures 13 is small, then the size of the ZnO nano-micro rods 14 will be larger than that of the apertures 13. In addition, the layout of the ZnO nano-micro rods 14 may be any regular or irregular pattern or array.

Because GaN has crystal structure similar or same as ZnO, i.e., they are lattice-matched, the ZnO nano-micro rods 14 grown on the first GaN layer 11 will have a crystal structure that is quite orientated and same as the GaN, i.e., a hexagonal wurtzite crystal structure, regardless of the shape of the apertures 13.

Then, the first GaN layer 11 is etched to form the GaN nano-micro rods 15, by using ZnO nano-micro rods 14 as the etching mask. Method for performing the etching may employ conventional dry etching, wet etching, or both. In this embodiment, a dry etching is firstly performed by the reactive ion etching (RIE), and a wet etching is then performed by an etching solution such as potassium hydroxide (KOH). In another embodiment, the order of the wet etching and the dry etching may be changed. The etched GaN nano-micro rods 15 will have the crystal structure same as the ZnO nano-micro rods 14, i.e., a hexagonal wurtzite crystal structure. In addition, the etched GaN nano-micro rods 15 have perfect crystal surface, which is beneficial for the later epitaxy process. In addition, the pattern, position, size, and the height of the GaN nano-micro rods 15 will be determined by the pattern, position, size, and the height of the ZnO nano-micro rods 14. If the layout of the as-prepared GaN nano-micro rods 15 is an array, the period, i.e., the distance between the center of one GaN nano-micro rod and the center of the adjacent one, ranges between about 100 nm and thousands of micrometer (m). Notice that if a conventional mask is used as the etching mask and then use the same etching method to form the GaN nano-micro rods, it will suffer from to control the pattern, size, and height of the GaN rods; in addition, the exposed crystal surface of the grown GaN rods is too defective to grow other materials by epitaxy process.

In addition, the above embodiment may have many modifications. Except the hydrothermal synthesis, the ZnO nano-micro rods 14 may be fabricated by molecular beam epitaxy (MBE), chemical vapor deposition (CVD), evaporation, sputtering, atomic layer deposition, electrochemical deposition, pulsed laser deposition, metalorganic chemical vapor deposition, or other methods known in the art.

In addition, the substrate may be made of semiconductors, metals, quartz, glass, flexible plastics, and other suitable substrates. The semiconductor may comprise sapphire, silicon (Si), gallium nitride (GaN), aluminum nitride (AlN), aluminum gallium nitride (AlGaN), and silicon carbon (SiC). The flexible plastics may comprise polyethylene terephthalate (PET).

In addition, in another embodiment, a GaN buffer layer (not shown) is firstly formed on the substrate 10, and then the first GaN layer 11 is formed on the GaN buffer layer. In addition, other semiconductors with same or similar crystal structure to GaN may be employed to replace the ZnO, as the etching mask. In addition, other binary, ternary, or quaternary compounds of group III and group V semiconductors, such as zinc selenium (ZnSe), may be used to replace GaN.

Then, the as-prepared GaN nano-micro rods 15 with perfect crystal surface can be used as a seed to grow other materials on its surface. For example, a semiconductor nitride or quantum well may be formed on the GaN nano-micro rods 15 and the as-prepared structure is used to produce optoelectronics or electronics.

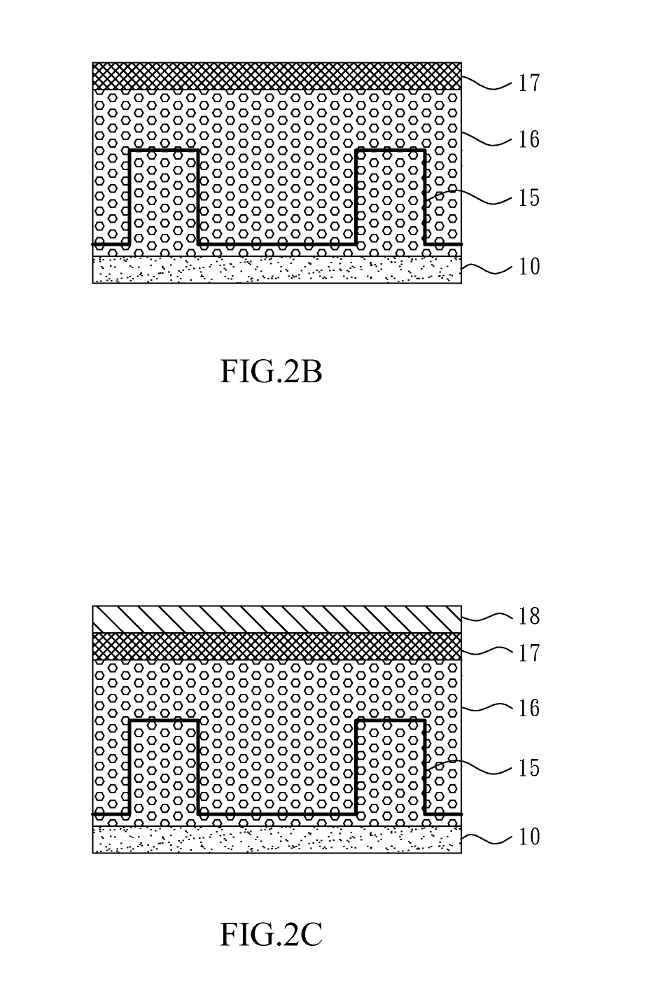

FIG. 2A to FIG. 2C show one or more epitaxy processes are performed on the as-prepared structure shown in FIG. 1F′; the same processes may be applied to the structure shown in FIG. 1F.

Referring to FIG. 2A, by using the epitaxy process, such as MOCVD, MBE, or MEMOCVD, a second GaN layer 16 is formed to cover the GaN nano-micro rods 15. During the epitaxy process, the lateral epitaxial rate may be controlled to be greater than the vertical epitaxial rate. Compared to the first GaN layer 11, the dislocation density of the second GaN layer 16 can be reduced by at least an order.

Referring to FIG. 2B, then, an epitaxial layer 17 may be formed on the second GaN layer 16. The epitaxial layer 17 may be a multiple quantum well (MQW) such as InGaN/GaN, or one or more nitride epitaxial layers. The multiple quantum well can be used as a light-emitting layer of a light-emitting diode or a laser diode. The nitride epitaxial structure can be used to produce photovoltaic devices, transistors, integrated circuits, and so on.

Referring to FIG. 2C, then a gallium nitride (GaN) cladding layer 18 is formed on the epitaxial layer 17. If both the first GaN layer 11 and second GaN layer 16 are n-type, then the GaN cladding layer 18 is p-type, and vice versa. Then two electrodes (not shown) may be formed to respectively contact the second GaN layer 16 and the GaN cladding layer 18, and thus a light-emitting diode or a laser diode is formed.

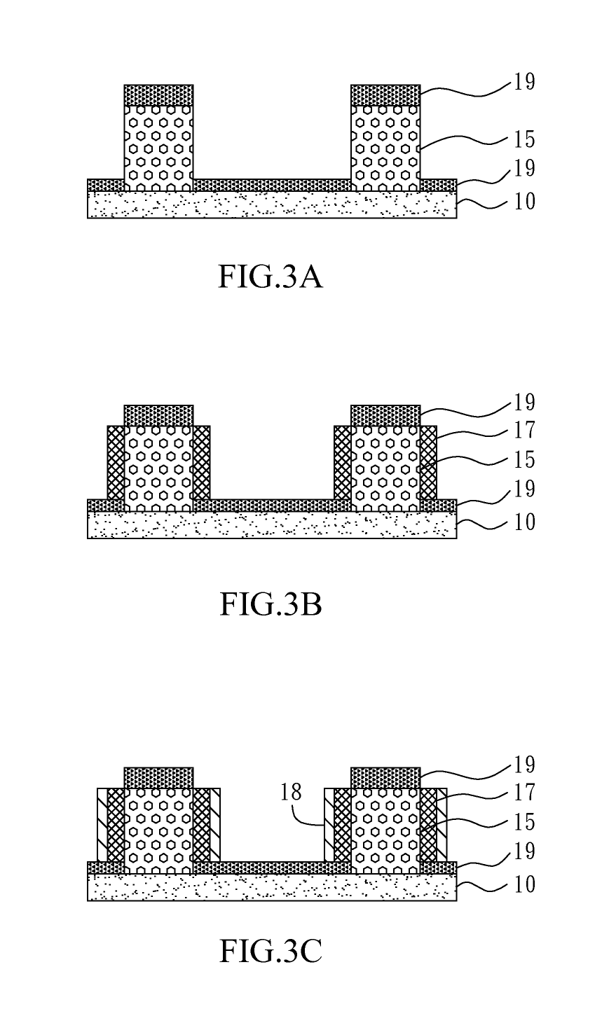

FIG. 3A to FIG. 3C show one or more epitaxy processes are performed on the as-prepared structure shown in FIG. 1F; the same processes may be applied to the structure shown in FIG. 1F′.

Referring to FIG. 3A, an insulating layer 19, such as silicon dioxide (SiO₂) or other oxides, is formed on the top surface of the GaN nano-micro rods 15 and the exposed surface of the substrate 10. (In case of FIG. 1F, the insulating layer 19 is formed on the top surface of the GaN nano-micro rods 15 and the GaN surface S; in this text, the two above-mentioned surfaces can be referred to as “the top surface of the GaN nano-micro rods” for short.)

Referring to FIG. 3B, then, use the sidewall of the GaN nano-micro rods 15 as the seed and employ an above-mentioned epitaxy process to grow an epitaxy layer 17 on the sidewall of the GaN nano-micro rods 15. During the epitaxy process, the lateral epitaxial rate may be controlled to be greater than the vertical epitaxial rate. The epitaxial layer 17 may be a multiple quantum well (MQW) such as InGaN/GaN, or one or more nitride epitaxial layers. The multiple quantum well can be used as a light-emitting layer of a light-emitting diode or a laser diode. The nitride epitaxial structure can be used to produce photovoltaic devices, transistors, integrated circuits, and so on.

Referring to FIG. 3C, then a gallium nitride (GaN) cladding layer 18 is formed on the sidewall of the epitaxial layer 17. If the GaN nano-micro rods 15 are n-type, then the GaN cladding; layer 18 is p-type, and vice versa. Then two electrodes (not shown) may be formed to respectively contact the GaN nano-micro rods 15 and the GaN cladding layer 18, and thus a light-emitting diode or a laser diode is formed.

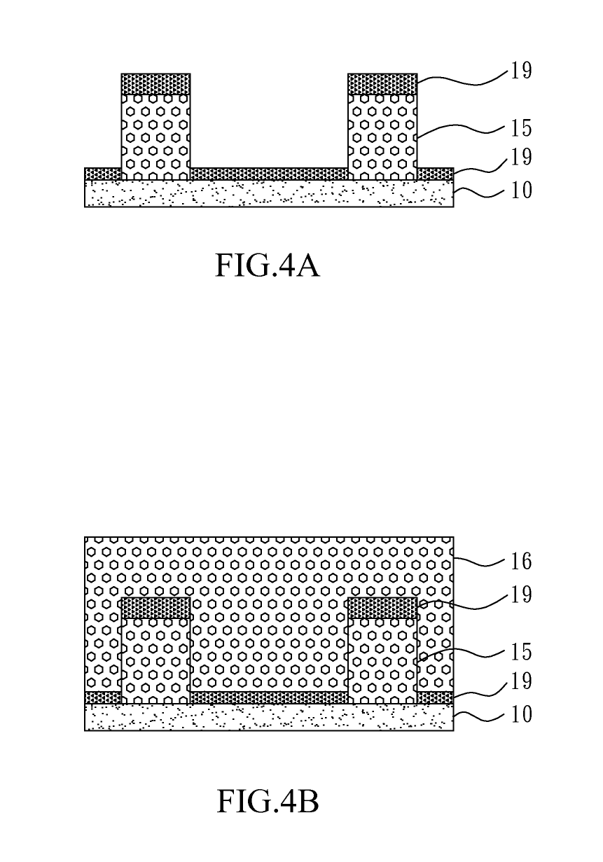

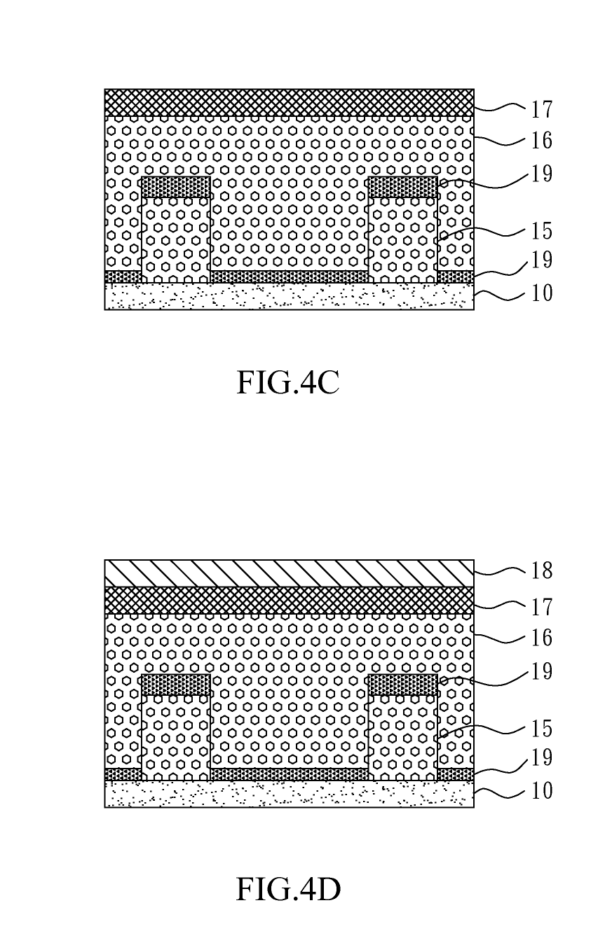

FIG. 4A to FIG. 4D show one or more epitaxy processes are performed on the as-prepared structure shown in FIG. 1F; the same processes may be applied to the structure shown in FIG. 1F′.

Referring to FIG. 4A, an insulating layer 19, such as silicon dioxide (SiO₂) or other oxides, is formed on the top surface of the GaN nano-micro rods 15 and the exposed surface of the substrate 10.

Referring to FIG. 4B, use the sidewall of the GaN nano-micro rods 15 as the seed and employ an above-mentioned epitaxy process to grow a second GaN layer 16 to cover the GaN nano-micro rods 15. During the epitaxy process, the lateral epitaxial rate is controlled to be greater than the vertical epitaxial rate. Because the sidewall of the GaN nano-micro rods 15 is non-polarized m-plane and the top surface of which is polarized c-plane, the dislocation density of the second GaN layer 16 can be reduced by about three or four orders in comparison to the first GaN layer 11.

Referring to FIG. 4C, then, an epitaxial layer 17 is formed on the second GaN layer 16 by the epitaxy process. The epitaxial layer 17 may be a multiple quantum well (MQW) such as InGaN/GaN, or one or more nitride epitaxial layers. The multiple quantum well can be used as a light-emitting layer of a light-emitting diode or a laser diode. The nitride epitaxial structure can be used to produce photovoltaic devices, transistors, integrated circuits, and so on.

Referring to FIG. 4D, then a gallium nitride (GaN) cladding layer 18 is formed on the epitaxial layer 17. If both the first GaN layer 11 and second GaN layer 16 are n-type, then the GaN cladding layer 18 is p-type, and vice versa. Then two electrodes (not shown) may be formed to respectively contact the second GaN layer 16 and the GaN cladding layer 18, and thus a light-emitting diode or a laser diode is formed.

Although specific embodiments have been illustrated and described, it will be appreciated by those skilled in the art that various modifications may be made without departing from the scope of the present invention, which is intended to be limited solely by the appended claims.

What is claimed is:

1. A method for forming semiconductor nano-micro rods, comprising the steps of
providing a substrate;
forming a first semiconductor epitaxial layer on the substrate;
forming a photoresist layer or a barrier layer on the first semiconductor epitaxial layer and defining a plurality of apertures in the photoresist layer or the barrier layer;
respectively growing a semiconductor nano-micro rod mask on each of the apertures; and
etching the first semiconductor epitaxial layer by the semiconductor nano-micro rod masks to form a plurality of semiconductor nano-micro rods.

2. The method as recited in claim 1, wherein the semiconductor nano-micro rod masks and the first semiconductor epitaxial layer are lattice-matched.

3. The method as recited in claim 1, wherein the semiconductor nano-micro rod masks comprise zinc oxide (ZnO).

4. The method as recited in claim 1, wherein the first semiconductor epitaxial layer comprises gallium nitride (GaN).

5. The method as recited in claim 1, wherein the pattern, position, size, and the height of the semiconductor nano-micro rods will be determined by the pattern, position, size, and the height of the semiconductor nano-micro rod masks.

6. The method as recited in claim 1, wherein the semiconductor nano-micro rod masks are formed by hydrothermal synthesis.

7. The method as recited in claim 1, wherein the semiconductor nano-micro rod masks are formed by molecular beam epitaxy (MBE), chemical vapor deposition (CVD), evaporation, sputtering, atomic layer deposition, electrochemical deposition, pulsed laser deposition, or metalorganic chemical vapor deposition.

8. The method as recited in claim 1, wherein the layout of the semiconductor nano-micro rod masks is a regular or irregular pattern or array.

9. The method as recited in claim 1, wherein the plurality of semiconductor nano-micro rods are formed by dry etching, wet etching, or both.

10. The method as recited in claim 1, wherein the substrate is made of semiconductors, metals, quartz, glass, or flexible plastics.

11. The method as recited in claim 10, wherein the semiconductor comprises sapphire, silicon (Si), gallium nitride (GaN), aluminum nitride (AlN), aluminum gallium nitride (AlGaN), and silicon carbon (SiC).

12. The method as recited in claim 1, further comprising using an epitaxy process to form a second semiconductor epitaxial layer to cover the plurality of semiconductor nano-micro rods, wherein the first semiconductor epitaxial layer and the second semiconductor epitaxial layer are formed by the same material, and the dislocation density of the second semiconductor epitaxial layer is less than that of the first semiconductor epitaxial layer.

13. The method as recited in claim 12, wherein a lateral epitaxial rate is controlled to be greater than a vertical epitaxial rate during the epitaxy process.

14. The method as recited in claim 12, further comprising forming a multiple quantum well on the second semiconductor epitaxial layer, wherein the multiple quantum well functions as a light-emitting layer of a light-emitting diode or a laser diode.

15. The method as recited in claim 14, further comprising forming a semiconductor cladding layer on the multiple quantum well, and forming two electrodes to respectively contact the semiconductor cladding layer and the second semiconductor epitaxial layer.

16. The method as recited in claim 12, further comprising forming one or more nitride epitaxial layers on the second semiconductor epitaxial layer, wherein the one or more nitride epitaxial layers are used to produce a photovoltaic device, a transistor, or an integrated circuit.

17. The method as recited in claim 1, further comprising:
forming an insulating layer on the top surface of the plurality of semiconductor nano-micro rods and an exposed surface of the substrate; and
using an epitaxy process to form an epitaxial layer on the sidewall of each of the plurality of semiconductor nano-micro rods, wherein a lateral epitaxial rate is controlled to be greater than a vertical epitaxial rate during the epitaxy process.

18. The method as recited in claim 17, wherein the epitaxial layer comprises a multiple quantum well that functions as a light-emitting layer of a light-emitting diode or a laser diode.

19. The method as recited in claim 18, further comprising forming a semiconductor cladding layer on the sidewall of the multiple quantum well, and forming two electrodes to respectively contact the semiconductor cladding layer and the semiconductor nano-micro rod.

20. The method as recited in claim 17, wherein the epitaxial layer comprises one or more nitride epitaxial layers used to produce a photovoltaic device, a transistor, or an integrated circuit.

21. The method as recited in claim 1, further comprising:
forming an insulating layer on the top surface of the plurality of semiconductor nano-micro rods and an exposed surface of the substrate; and
using an epitaxy process to form a second semiconductor epitaxial layer to cover the plurality of semiconductor nano-micro rods, wherein a lateral epitaxial rate is controlled to be greater than a vertical epitaxial rate during the epitaxy process, the first semiconductor epitaxial layer and the second semiconductor epitaxial layer are formed by the same material, and the dislocation density of the second semiconductor epitaxial layer is less than that of the first semiconductor epitaxial layer.

22. The method as recited in claim 21, further comprising forming a multiple quantum well on the second semiconductor epitaxial layer, wherein the multiple quantum well functions as a light-emitting layer of a light-emitting diode or a laser diode.

23. The method as recited in claim 22, further comprising forming a semiconductor cladding layer on the multiple quantum well, and forming two electrodes to respectively contact the semiconductor cladding layer and the second semiconductor epitaxial layer.

24. The method as recited in claim 21, further comprising forming one or more nitride epitaxial layers on the second semiconductor epitaxial layer, wherein the one or more nitride epitaxial layers are used to produce a photovoltaic device, a transistor, or an integrated circuit.

25. The method as recited in claim 1, wherein the layout of the semiconductor nano-micro rods is an array, and the distance between centers of two adjacent GaN nano-micro rods ranges from about 100 nm to thousands of micrometer (μm).

26. The method as recited in claim 1, further comprising removing the photoresist layer or the barrier layer before the first semiconductor epitaxial layer is etched to form the plurality of semiconductor nano-micro rods.
